(19) United States
(12) Patent Application Publication
(10) Pub. No.: US 2005/0094694 A1
(43) Pub. Date: May 5, 2005

(54) Semiconductor laser device and optical pick-up apparatus using semiconductor laser device

(76) Inventors: Kiyoshi Fujihara, Ootsu-shi (JP); Akira Ueno, Katano-shi (JP); Yoshiaki Matsuda, Mukoh-shi (JP); Hideyuki Nakanishi, Ootsu-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/979,396

(22) Filed: Nov. 3, 2004

(30) Foreign Application Priority Data
Nov. 5, 2003 (JP) 2003-375970

(51) Int. Cl. H01S 5/00

(52) U.S. Cl. 372/43

(57) ABSTRACT

An object of the present invention is to provide a semiconductor laser device that has a simple structure that can easily be constructed, and can dissipate heat easily, and can improve its functionality and realize miniaturizing concurrently. The semiconductor laser device composes a metal plate 100 that is substantially the same as the bigger one of the widths of the silicon substrate 120 and the flexible sheet 130, a semiconductor laser element 110, a silicon substrate 120 into which a light detection circuit and a signal processing circuit are integrated, a flexible sheet 130, a wire 140 and an optical element 150. The flexible sheet 130 is divided into two on the metal plate 100, and the two divided flexible sheet 130 are positioned face to face sandwiching the silicon substrate 120.

### BACKGROUND OF THE INVENTION

(1) Field of the Invention

This present invention relates to a semiconductor laser device, especially relates to a semiconductor laser device comprising an optical pick-up that writes/reads information on/from a recording medium such as an optical disc, for example, a digital versatile disc (DVD), a compact disc (CD) or the like and an optical pick-up apparatus using the semiconductor laser device.

(2) Description of the Related Art

Recently, as recording media not only for music information but also for video information, optical discs of a CD system such as a CD-ROM, a CD-R, a CD-RW and the like and a DVD system such as a DVD-ROM, a DVD-RW, a DVD-RAM and the like have rapidly become popular. There are strong requests of improving optical pick-up apparatuses that are the hearts of these optical disc drives, these requests are: realizing the operation for high-power output for performing high double-speed recording; improving their functionality for handling both CDs and DVDs; and miniaturizing optical disc drives accompanied by the slimming down of the optical disc drives. Therefore, it is essential that a semiconductor laser device used for an optical pick-up apparatus be improved in heat dissipation of a package so as to realize the operation for high-power output, have more pins so as to improve its functionality and further, have a narrow package structure so as to slim down.

An apparatus described in U.S. Pat. No. 3,412,609 publication proposed by the applicant is mentioned as an example of a semiconductor laser device of a conventional optical pick-up apparatus, and the structure of the semiconductor laser device will be explained below.

FIG. 1A is a top view of a conventional semiconductor laser device, and FIG. 1B is a section view (cut on the X-X′ line in FIG. 1A) of the semiconductor laser device.

The semiconductor laser device shown in FIGS. 1A and 1B composes a lead frame 1400, a package 1410 made of plastic mold, a silicon substrate 1420 into which the light receiving elements 1440 are integrated, the silicon substrate 1420 having a 45° mirror for reflecting the laser beam to the upper part of the package 1410 and a circuit for receiving and processing the light reflected on the optical disc, a semiconductor laser element 1430 mounted on the center of the package 1410 through the silicon substrate 1420 and a hologram element 1450 with a grating pattern 1460 formed on its under surface and a hologram pattern 1470 formed on its top surface.

In the semiconductor laser device having the above-mentioned structure, an outgoing beam 1480 from the semiconductor laser element 1430 is reflected over the package 1410, is diffracted on and passes through the grating pattern 1460, passes through optical components (not shown in any figure) such as a collimate lens and an object lens and reaches an optical disc (not shown in any figure). After that, the reflected light 1490 from the optical disc passes through the same path, is diffracted on the hologram pattern 1470, and launches into the light receiving elements 1440 that are integrated with a signal processing circuit.

In the case of realizing the operation for high-power output, improving its functionality and miniaturizing an optical pick-up apparatus by the semiconductor laser device having the above-mentioned structure, two main problems occur. One of them is the improvement in heat dissipation along with the realization of the operation for high-power output, and the other is narrowing pin pitches along with the improvements in functionality and the miniaturization.

Generally, high-power output of 200 mW or more is needed as a light output from the semiconductor laser device in the optical disc drive for high-speed recording. Accompanied by this, as the drive current of the laser increases, the temperature of the laser increases and the reliability of the laser decreases, it becomes necessary that the heat generated by the laser be radiated efficiently in order to drive the laser in a way that it is not affected by the changes in environmental temperature. However, the conventional above-mentioned semiconductor laser device has a structure whose heat resistance is high and cannot dissipate heat efficiently because the package itself is covered with plastic whose heat conductivity is low (the heat conductivity is about 0.5 W/m/deg).

Also, the increase in the number of pins along with the improvement in functionality is restricted in the case of miniaturizing the package in the above-mentioned semiconductor laser device, which generates the necessity of narrowing pin pitches so as to increase the number of pins, but the pitch cannot be made narrower than about 0.4 mm because it is the limit in processing the present lead frame.

Here is a semiconductor laser device described in patent 2003-67959 publication as an example of semiconductor laser devices that can solve the problem of the improvement in heat dissipation.

FIG. 2B is a top view of the semiconductor laser device described in patent 2003-67959 publication, FIG. 2A is a section view (cut on the X-X′ line in FIG. 2B) of the semiconductor laser device, and FIG. 2C is a section view (cut on the Y-Y′ line in FIG. 2B) of the semiconductor laser device.

The semiconductor laser device shown as FIGS. 2A, 2B and 2C composes a laser unit part 1500 that mounts a semiconductor laser element, an optical detector 1510 that mounts light receiving elements, a metal substrate 1520 on which the laser unit part 1500 and the optical detector 1510 are mounted and the plastic substrate 1530 which has the opening in the part on which the laser unit part 1500 and the optical detector 1510 are mounted, on which a wiring pattern is formed, and which is attached to the metal substrate 1520.

The semiconductor laser device having the above-mentioned structure can efficiently dissipate heat generated by the semiconductor laser element from the back of the metal substrate, and thus it can solve the problem of the improvement in heat dissipation.

Also, in the other hand, here is a semiconductor laser device described in patent 2002-198605 as a semiconductor laser device that can solve the problem of narrowing pin pitches.

FIG. 3 is an external view of the semiconductor laser device described in patent 2002-198605 publication.

The semiconductor laser device shown in FIG. 3 composes a three-dimentional metal island 1600, a flexible sheet 1640 that-has an outer part 1610 and a folding part 1620 and that is bonded to a wire in an upper end part 1630, a semiconductor laser element 1650 and a light receiving element 1660. Here, considering mounting the semiconductor laser device on the optical disc drive, the wiring space of the outer part 1610 is set wide.

A flexible sheet is used as a wiring substrate in the semiconductor laser device that has the above-mentioned structure, which enables reducing the wiring space, and thus it is possible to solve the problem of narrowing pin pitches. Also, it is possible to solve the problem of the improvement in heat dissipation at the same time because the device can efficiently dissipate heat generated by the semiconductor laser element from the back of the metal island.

However, narrowing the width of the device in its miniaturization results in narrowing only the area for mounting a laser unit part and an optical detector because a plastic substrate is needed for keeping an opening in the semiconductor laser device described in the above-mentioned patent 2003-67959 publication. However, decreasing the space for mounting a laser unit part and an optical detector is undesirable when considering the improvement in functionality. Therefore, there is a problem that it is difficult to realize its miniaturization and improve its functionality concurrently. Further, in the case of considering achieving higher-integration for including an optical element used when mounting a device on an optical disc drive, there is a problem that it is impossible to glue and fix the optical element on the package in the semiconductor laser device described in the above-mentioned patent 2003-67959 publication because there is no description concerning the semiconductor laser device having an optical element of a diffraction grating and the like in the above-mentioned patent 2003-67959.

Also, as the semiconductor laser device described in the above-mentioned patent 2002-198605 publication is structured in a way that light emitting elements and light receiving elements are mounted on a separate three-dimentional part respectively, and a flexible sheet is attached to another part, its construction method becomes complicated, and thus there is a problem that not only reducing the working time but also securing positional accuracy become difficult. Further, as the terminal part of the flexible sheet that electrically connects the light emitting elements and the light receiving elements using a wire bond is bent like shown in FIG. 3 and is attached to the metal island, there is a problem that the operation becomes complicated and keeping the adhesive strength becomes difficult.

### SUMMARY OF THE INVENTION

Therefore, the present invention is invented considering these problems and the first object of the present invention is to provide a semiconductor laser device that has a simple structure that can easily be constructed, can dissipate heat easily and realize its miniaturization and improvement in its functionality concurrently.

Also, the second object of the present invention is to provide a semiconductor laser device that enables realizing higher integration for including an optical element.

In order to achieve the above-mentioned object, the semiconductor laser device of the present invention includes: a light receiving and emitting unit having light emitting elements and light receiving elements; a first wiring substrate; and a metal plate on which the light receiving and emitting unit, and the first wiring substrate are mounted, wherein the light receiving and emitting unit, and the first wiring substrate are arranged next to each other on the metal plate, the first wiring substrate has a first terminal group composed of a plurality of first terminals connected to the light receiving and emitting unit, and the width of the metal plate is substantially the same as a bigger one of widths of the first wiring substrate and the light receiving and emitting unit. Here, the semiconductor laser device further composes an optical element that passes through the incoming light into the light receiving elements and the outgoing light from the light emitting elements, and the optical element may be mounted on the first and second wiring substrates.

In this way, the size of the semiconductor laser device is decided depending on only the width of the light receiving and emitting unit and the wiring substrate, which makes it possible to realize a semiconductor laser device that can realize both the improvement in its functionality and its miniaturization concurrently. Also, it is possible to realize a semiconductor laser device that can dissipate heat easily because the part below the light receiving and emitting units that are heat sources is made of metal. Further, an effect that a simply-constructable semiconductor laser device can be realized is obtained because, with the structure, components are mounted on the surface of the metal plate.

Here, the semiconductor laser device further includes a second wiring substrate mounted on the metal plate facing the first wiring substrate sandwiching the light receiving and emitting part, wherein the second wiring substrate has a second terminal group composed of a plurality of second terminals connected to the light receiving and emitting unit, and a width of the second wiring substrate is substantially the same as the width of the first wiring substrate, the second terminal group is made by arranging a plurality of second terminals in the width direction.

In this way, the semiconductor laser device composes a plurality of terminals that can be connected to the light receiving and emitting unit, and thus it is possible to realize a semiconductor laser device that can have more pins accompanied by the improvement in its functionality.

Also, the semiconductor laser device further compises: an external wiring substrate that pulls out wires of the first and second wiring substrates outside the metal plate, the external wiring substrate has a plurality of external terminals electrically connected to the terminals in the first and second terminal groups, and space between the external terminals is wider than space between terminals in the first terminal group and space between terminals in the second terminal group.

In this way, it is possible to widen the space between terminals connected to external apparatuses, which makes it possible to realize a semiconductor laser device that can easily be connected electrically at the time of mounting the semiconductor laser device on the optical disc drive.

Also, in the semiconductor laser device, the first and second wiring substrates and the external wiring substrate are a flexible sheet where metal wires are wrapped in plastic.

In this way, as a flexible sheet is applied as a wiring substrate, it is possible to realize a semiconductor laser device that can have more pins by reducing the space between wires.

Also, processing that enables increasing bendability may be performed on the external wiring substrate.

This processing makes a starting point of bending on the wiring substrate, which makes it possible to realize a semiconductor laser device that reduces the load on the light receiving and emitting unit generated at the time of bending the wiring substrate.

Also, in the semiconductor laser device, the first and second terminal groups are respectively composed of a plurality of the first and second terminals that are arranged in a width direction that is perpendicular to a longitudinal direction where the light receiving and emitting unit, and the first and second wiring substrates are arranged, and the first and second wiring substrates have a plural rows of the first and second terminal groups.

In this way, it is possible to realize a semiconductor laser device that can secure a terminal area necessary for wire bonding even in the case of having more pins.

Also, the area of the first and second terminals in a row that is adjacent to the light receiving and emitting unit among the first and second terminal groups in the plurality of rows may be larger than the area of the first and second terminals in a row that is not adjacent to the light receiving and emitting unit.

In this way, it is possible to wider the terminal areas than the areas which are actually touched by wires, which makes it easier to bond wires in construction and makes it possible to realize a semiconductor laser device that avoids interference between wires.

Also, in the semiconductor laser device, a part of wires of the first and second wiring substrates and the external wiring substrate have bigger cross-sectional areas than the other wires.

In this way, as it is possible to enlarge the cross-sectional area of a wire to which high electric current is applied, it is possible to reduce the increase in generating heat in a wire to which high electric current is applied and realize a semiconductor laser device that constrains the increase in temperature of the whole semiconductor laser device.

Also, the first and second wiring substrates may have a plurality of terminals for evaluation that can be electrically connected externally.

In this way, as the wiring substrate has terminals for evaluation on the metal plate, it is possible to realize a semiconductor laser device that enables evaluating the light emitting and receiving elements in the middle of constructing the semiconductor laser device.

Also, the semiconductor laser device composes optical element that passes through incoming light into the light receiving elements and the outgoing light from the light emitting elements, an optical element supporting unit that has greater thickness than other parts is formed on the first and second wiring substrates, and the optical element may be mounted on the optical element supporting unit of the first and second wiring substrates.

In this way, it is possible to secure a distance between the light receiving and emitting unit and the optical element without performing the process on the optical element to be mounted, which makes it possible to realize a semiconductor laser device that eliminates the process of optical element.

Also, a pattern for diffracting the incoming light into the optical element may be formed in the optical element.

In this way, it is possible to realize a semiconductor laser device that enables high-integration for including an optical element. Also, a diffraction grating or a hologram element that is mounted at the time of constructing a conventional disc drive is integrated into a semiconductor laser device, which makes it possible to reduce the number of components as optical pick-up apparatuses and realize a semiconductor laser device that can reduce the cost.

Also, the peripheral part of the optical element may be arc-shaped.

In this way, making, the shape of the semiconductor laser device insertion part of the optical pick-up apparatus, suitable for the arc-shaped optical element that enables mounting an optical element on the optical pick-up apparatus only by the rotation and adjustment, which enables realizing a semiconductor laser device that makes it easier to construct the optical pick-up apparatus.

Also, in the semiconductor laser device, the metal plate has exposed parts where neither the first and second wiring substrates nor the light receiving and emitting unit, is mounted at both ends of the longitudinal direction where the light receiving and emitting unit, and the first and second wiring substrates are arranged.

In this way, making the front surfaces of the exposed metal plate touch the optical pick-up apparatus on which a semiconductor laser device is mounted enables dissipating heat widely not only from the back surface of the metal plate but also from the front surface of the metal plate, which makes it possible to realize a semiconductor laser device that can dissipate heat efficiently.

Also notches for fixation are formed at opposite positions along with the width direction on the exposed parts of the metal plate.

In this way, as the metal plate is surely fixed in a way that light emitting points do not move at the time of adjusting and fixing the optical element, which makes it possible to realize a semiconductor laser device that enables stable construction.

Also, the metal plate may have an arc at both sides in the lengthwise.

In this way, making the shape of the semiconductor laser device insertion part of the optical pick-up apparatus suitable for the arc-shaped metal plate makes it possible to rotate and adjust the semiconductor laser device without putting load on the optical element, bonding part and the like, and thus it becomes possible to realize a semiconductor laser device preventing a breakdown that makes it impossible to obtain a desired properties from occurring because of the load in placing and adjusting the optical pick-up apparatus.

Also, the width of the exposed part of the metal plate may be narrower than the width of the other part of the metal plate.

In this way, the end part of the metal plate does not extend off the optical pick-up apparatus even in the case of rotating and adjusting the semiconductor laser device when mounting it on the optical pick-up apparatus, it is possible to realize a semiconductor laser device that can be stored within a desirable size after mounting the semiconductor laser device on the optical pick-up apparatus.

Also, the present invention may be an optical pick-up apparatus comprising the above-mentioned semiconductor laser device.

In this way, the semiconductor laser device that can realize the improvement in its functionality and its miniaturization and can dissipate heat efficiently is mounted on the optical pick-up apparatus, and thus it is possible to realize an optical pick-up apparatus that can realize its miniaturization, the improvement in its functionality and the realization of the operation for high-power output.

As made clear in the above-mentioned explanation, according to the semiconductor laser device concerning the present invention, the size of the semiconductor laser device is decided based on the width of the light receiving and emitting unit and the wiring substrate, which generates an effect that a semiconductor laser device that can realize the improvement in its functionality and its miniaturization.

Also, according to the semiconductor laser device concerning the present invention, as the semiconductor laser device has the structure for mounting respective components on the surface and no complicated method is required for its construction, it is possible to obtain an effect of realizing a semiconductor laser device that can easily be constructed.

Also, according to the semiconductor laser device concerning the present invention, a flexible sheet is applied as a wiring substrate with fine pitches, which generates an effect of realizing a semiconductor laser device that concurrently realizes having more pins accompanied by the improvement in its functionality and its sliming down. In other words, it is possible to realize a slim multi-functional semiconductor laser device.

Also, according to the semiconductor laser device concerning the present invention, as the part below the light receiving and emitting unit that is the source of heat is made of metal, an effect of realizing a semiconductor laser device that can dissipate heat efficiently can be produced. In other words, it is possible to realize an optical disc drive that can be used in higher temperature than a conventional one.

Also, according to the semiconductor laser device concerning the present invention, simply attaching supplementary components to the wiring substrates and mounting an optical element on the supplementary components eliminates the necessity of processing an optical element in order to prevent the optical element from touching the wire, which produces an effect of realizing a semiconductor laser device that can be easily constructed, whose properties are stable and that is low-cost.

Also, according to the semiconductor laser device concerning the present invention, the processing for making the starting point of bending is performed on the wiring substrates, and it is possible to prevent the occurrence of a separation at the interface between the wiring substrate and the optical element that is glued and fixed on the wiring substrate and a separation at the interface between the metal plate and the wiring substrate at the time of bending the wiring substrate, which produces an effect of realizing a semiconductor laser device that prevents such separation caused by bending the wiring substrate. In other words, it is possible to realize a semiconductor laser device that does not take any stress at the time of mounting the semiconductor laser device on the optical pick-up apparatus.

Also, according to the semiconductor laser device concerning the present invention, as plural rows of terminal groups are formed on the wiring substrate, and arranging the plural rows of terminal groups in a hounds-tooth way enables making the pads lager than the actual wire touching area, an effect of preventing wire bonding from being performed incorrectly and realizing a semiconductor laser device that reduces troubles in construction. Further, it is possible to increase flexibility in wire-bonding (such as routing wires) and avoids the interference between wires, and thus it is possible to realize a semiconductor laser device that reduces troubles in construction.

Also, according to the semiconductor laser device concerning the present invention, it is possible to have a wire whose cross-sectional area is large as a wire through which high current flows, restrains heat generation in a wire accompanied by the application of electric current, and reduces thermal load to the semiconductor laser device, which produces an effect of securing the reliability of the laser, and thus it is possible to realize a semiconductor laser device that can operate stably.

Also, according to the semiconductor laser device concerning the present invention, an evaluation pad is formed on the wiring substrate on the metal plate, and it is possible to surely lay the probe on the evaluation pads so as to make the probe electrically touch the evaluation pads in the location adjustment at the time of mounting an optical element, which makes it possible to produce an effect of realizing a semiconductor laser device that can easily be adjusted optically even in the case of having more pins.

Also, according to the semiconductor laser device concerning the present invention, it is possible to have an optical element that diffracts the incoming light into the light receiving elements and the outgoing light from the light emitting elements and can integrate a diffraction grating or a hologram element that is conventionally mounted outside the semiconductor laser device, which produces an effect of realizing a semiconductor laser device that reduces the number of components of the optical disc drive.

Also, according to the semiconductor laser device concerning the present invention, the semiconductor laser device which composes the optical element whose peripheral part may be arc-shaped, and making, the shape of the semiconductor laser device insertion part of the optical pick-up apparatus, suitable for the arc-shaped optical element makes it possible to mount the semiconductor laser device on the optical pick-up apparatus only by rotating and adjusting the semiconductor laser device, which produces an effect of realizing the semiconductor laser device that can easily be constructed.

Also, according to the semiconductor laser device concerning the present invention, the metal plate has exposed parts that are not covered by the wiring substrate at its both ends and making the exposed parts in the front surface of this metal plate touch the optical pick-up apparatus makes it possible to dissipate heat widely from not only the back surface but also the front surface of the metal plate, and thus it is possible to obtain an effect of realizing a semiconductor laser device that can dissipate heat efficiently. In other words, it is possible to realize a high double-speed optical disc drive that can be used at higher environmental temperature than a conventional one and that can realize the operation for high-power output.

Also, according to the semiconductor laser device concerning the present invention, the metal plate has notches for fixation and is surely fixed, without any gap on the X-Y surface and the Z axis that is perpendicular to the X-Y surface of the metal plate on which light emitting and receiving elements and the substrate are mounted at the time of placing and adjusting an optical element, which produces an effect of realizing a semiconductor laser device that makes it easier to adjust the optical axis of the optical element.

Also, according to the semiconductor laser device concerning the present invention, the semiconductor laser device composes a metal plate whose both ends are arc-shaped, making the shape of the semiconductor laser device insertion part of the optical pick-up apparatus, suitable for the arc-shaped metal plate makes it possible to rotate and adjust the metal plate without putting load on the optical element, connection part and the like, and which produces an effect of realizing a semiconductor laser device that can prevent a breakdown that makes it impossible to obtain desired properties from occurring because of the load in constructing and adjusting the optical pick-up apparatus.

Also, according to the semiconductor laser device concerning the present invention, the metal plate of the semiconductor laser device has exposed parts whose width is shorter than the other part and the both ends of the metal plate do not extend off the optical pick-up apparatus even in the case of rotating and adjusting the semiconductor laser device when mounting the semiconductor laser device on the optical pick-up apparatus, which produces an effect of realizing a semiconductor laser device that can be stored within a desired size after mounting an optical element on the optical disc drive.

Also, according to the optical pick-up apparatus concerning the present invention, the optical pick-up apparatus comprises a heat dissipation block on the back surface of the metal plate of the semiconductor laser device, and also, the metal plate touches the optical pick-up apparatus, which produces an effect of realizing an optical pick-up apparatus that can operate stably because of its high heat dissipation property.

Also, according to the optical pick-up apparatus concerning the present invention, the semiconductor laser device applies a flexible sheet as a wiring substrate, and the flexible sheet of the semiconductor laser device and another flexible sheet are connected at the part connected by solders outside the optical pick-up apparatus, which produces an effect of realizing an optical pick-up apparatus that greatly reduces thermal load on the semiconductor laser device at the time of mounting a semiconductor laser device on the optical pick-up apparatus. In other words, it is possible to realize an optical disc drive that never cause the deterioration of its properties or the decreases of its reliability resulting from separations of nonreflective films formed on the grating pattern or the hologram pattern of the optical element or positional gaps of the optical element caused by the softening of the glue.

Therefore, the present invention makes it possible to provide a simple semiconductor laser device which can easily be constructed, which can dissipate heat easily and concurrently realizes its miniaturization and the improvement in its functionality, which enables realizing an optical pick-up apparatus which is miniaturized, is improved in functionality and capable of providing high-power output, and thus it is highly practical.

### FURTHER INFORMATION ABOUT TECHNICAL BACKGROUND TO THIS APPLICATION

The disclosure of Japanese Patent Application No. 2003-375970 filed on Nov. 5, 2003 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is a top view of a conventional semiconductor laser device descried in U.S. Pat. No. 3,412,609 publication;

FIG. 1B is a section view (cut on the X-X′ line in FIG. 1A) of the semiconductor laser device;

FIG. 2A is a section view (cut on the X-X′ line in FIG. 2B) of a conventional semiconductor laser device described in Japanese laid-open patent No. 2003-67959 publication;

FIG. 2B is a top view of the semiconductor laser device.

FIG. 2C is a section view (cut on the Y-Y′ line in FIG. 2B) of the semiconductor laser device;

FIG. 3 is an external view of a conventional semiconductor laser device described in patent No. 2002-198605 publication;

FIG. 4A is a top view of a semiconductor laser device in a first embodiment of the present invention;

FIG. 4B is a section view (cut on the X-X′ line in FIG. 4A) of the semiconductor laser device in the first embodiment;

FIG. 5A is a top view of a semiconductor laser device in a second embodiment;

FIG. 5B is a section view (cut on the X-X′ line in FIG. 5A) of the semiconductor laser device of the second embodiment;

FIG. 6 is a top view of a semiconductor laser device of a third embodiment;

FIG. 7 is a top view of a semiconductor laser device of a fourth embodiment;

FIG. 8 is a top view of a semiconductor laser device of a fifth embodiment;

FIG. 9A is a top view of a semiconductor laser device of a sixth embodiment;

FIG. 9B is a section view (cut on the X-X′ line in FIG. 9A) of the semiconductor laser device in the sixth embodiment;

FIG. 10A is a top view of a semiconductor laser device in a seventh embodiment;

FIG. 10B is a section view (cut on the X-X′ line in FIG. 10A) of the semiconductor laser device in the seventh embodiment;

FIG. 11A is a top view of an optical pick-up apparatus on which the semiconductor laser device of the seventh embodiment is mounted;

FIG. 11B is a section view of the optical pick-up apparatus 700;

FIG. 11C is a diagram for explaining irradiation locations of three beams on an optical disc 750;

FIG. 12A is a top view of an optical element 900 of the seventh embodiment;

FIG. 12B is a section view (cut on the X-X′ line in FIG. 12A) of the optical element 900 in the seventh embodiment;

FIG. 13 is a top view of a semiconductor laser device in an eighth embodiment;

FIG. 14 is an outline section view at the time of fixing the semiconductor laser device in the eighth embodiment;

FIG. 15 is a top view of the semiconductor laser device in a ninth embodiment;

FIG. 16A is a top view of an optical pick-up apparatus 1200 in a tenth embodiment; and

FIG. 16B is a section view of the optical pick-up apparatus in the tenth embodiment.

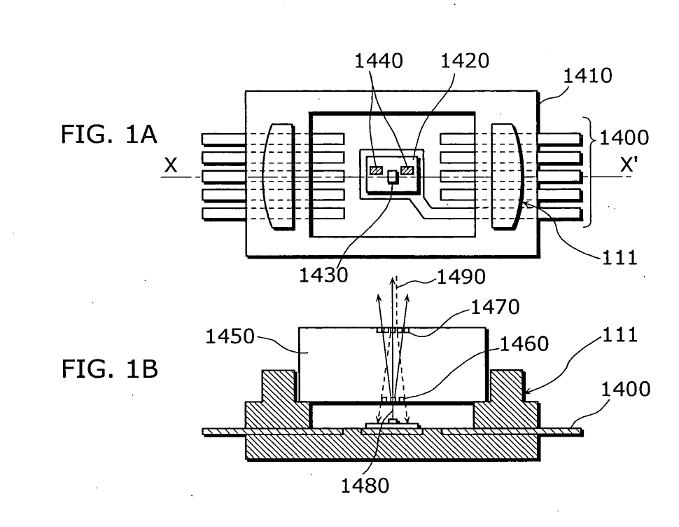

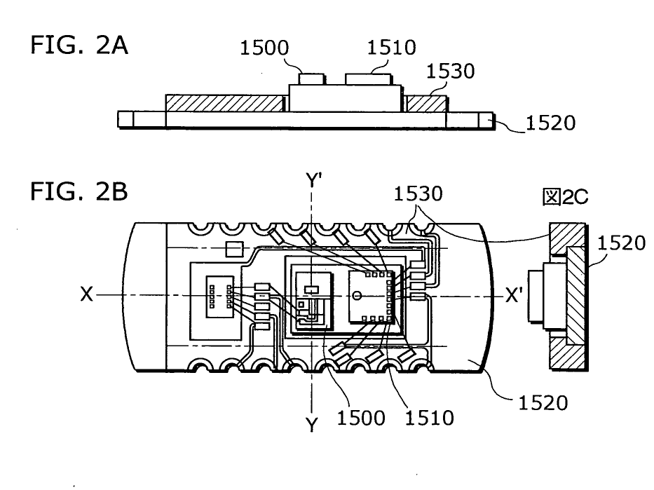

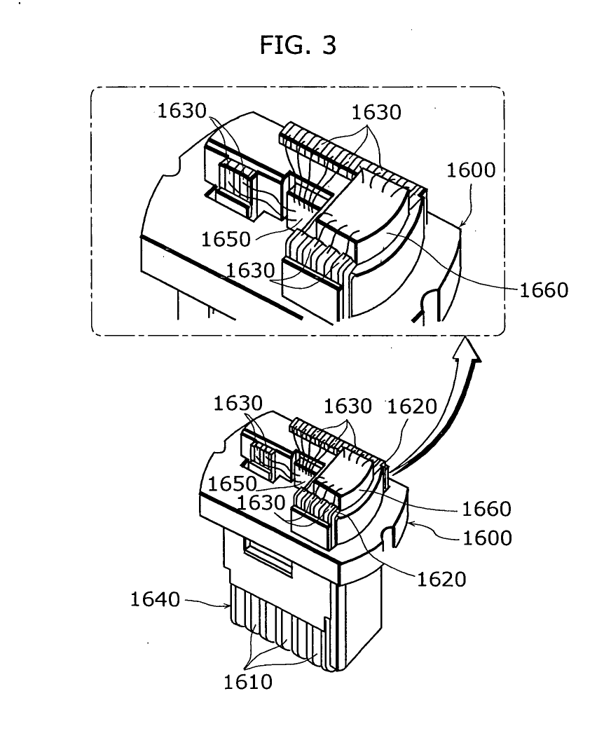

### DESCRIPTION OF THE PREFERRED EMBODIMENT(S)

### First Embodiment

A semiconductor laser device in a first embodiment of the present invention will be explained with reference to figures below.

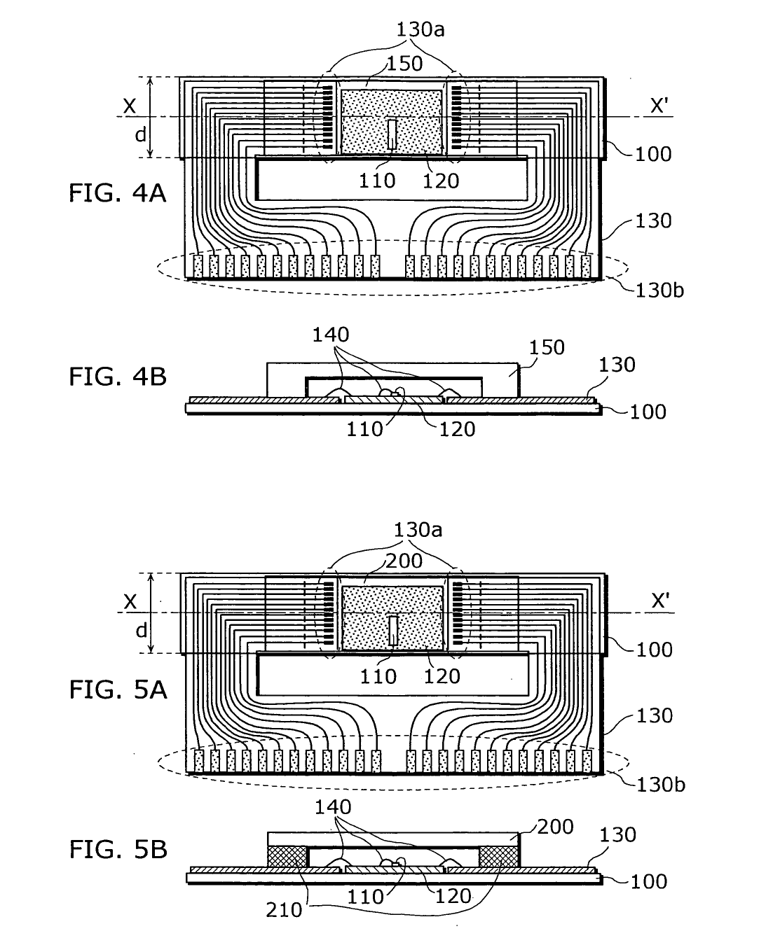

FIG. 4A is a top view of a semiconductor laser device of the first embodiment, and FIG. 4B is a section view (cut on the X-X′ line in FIG. 4A) of the semiconductor laser device.

An object of the semiconductor laser device of the embodiment is to realize a semiconductor laser device that can dissipate heat easily and can improve its functionality and realize its miniaturization concurrently. The semiconductor laser device composes (i) a metal plate 100 made of cupper to which nickel and gold is plated, (ii) a semiconductor laser element 110, (iii) a silicon substrate 120 on which 45° micro mirror is formed using the (111) plane, and light receiving elements and a signal processing circuit that are a light detection circuit are integrated into which the silicon substrate 120, (iv) a flexible sheet 130 is formed by wrapping wires made of metal such as cupper in plastic such as polyimide, (v) a wire 140 that is formed by gold wires and electrically connects the semiconductor laser element 110, a silicon substrate 120 and the flexible sheet 130 respectively, and (vi) an optical element 150 such as glass substrate that passes through the outgoing light from the semiconductor laser element 110 and the incoming light into the light receiving elements. Note that, the flexible sheet 130 that extends off the metal plate 100 is bended to be mounted at the time of mounting the semiconductor laser device on the optical disc drive.

The width of the metal plate 100 has the width “d” of, for example, such as 3 mm that is substantially the same as the bigger one of the width of the silicon substrate 120 and the width of the flexible sheet 130. At this time, the width “d” of the metal plate is 3 mm, therefore, for example, it can satisfy the request that the width be not more than 3 mm in order to realize a slim type optical disc drive for a note type personal computer. Note that the width of the metal plate 100 may be bigger than the bigger one of the width of the silicon substrate 120 and the width of the flexible sheet 130 as long as the width is within the range that can prevent the mounted metal plate 100 from extending off the optical pick-up apparatus of the semiconductor laser device.

The flexible sheet 130 is divided into two on the metal plate 100, and the two divided flexible sheet 130 are located face to face in a way that they sandwiches the silicon substrate 120. Here, the space between terminals in the distribution terminal part of the flexible sheet 130 varies from the inner part 130a on the metal plate 100 to the outer part 130b outside the metal plate 100. For example, in the inner part 130a, pads having an area of 0.1 mm×0.3 mm are arranged in the width direction, while in the outer part 130b, pads are arranged, for example, on condition that the width of each terminal is 0.35 mm and the width of each pitch is 0.65 mm in order not to cause electrical short and the like at the time of mounting the semiconductor laser device on the optical disc drive.

The optical element 150 is a concave as shown in FIG. 4B, and mounted on the flexible sheet 130 on the metal plate 100 covering the silicon substrate 120 and the wire 140.

In the semiconductor laser device having the above-mentioned structure, the light from the semiconductor laser element 110 is reflected perpendicularly by the mirror (not shown in any figures), passes through the optical element 150 and goes out to the outside. After that, the reflection light from the optical disc (not shown in any figures) passes through the same path, passes through the optical element 150 and launches into the light receiving element.

As explained up to this point, according to the semiconductor laser device of the embodiment, the silicon substrate 120 and the flexible sheet 130 are arranged on the metal plate 100. Therefore, unlike the Japanese laid-open patent No. 2003-67959 publication, that is a conventional technique, it is possible to realize a semiconductor laser device that meets the need of further improvement of its functionality because the area of the silicon substrate is not affected by the shape of the flexible sheet.

Also, according to the semiconductor laser device of the embodiment, the width of the metal plate 100 is substantially the same as the bigger one of the width of the silicon substrate 120 and the width of the flexible sheet 130. Therefore, the size of the semiconductor laser device is determined based on the width of the silicon substrate and the flexible sheet, and the semiconductor laser device of the embodiment can realize the semiconductor laser device that meets the need of further miniaturization because narrowing the bigger width of one of the silicon substrate and the flexible sheet makes it possible to miniaturize the semiconductor laser device.

Also, according to the semiconductor laser device of the embodiment, the semiconductor laser device can be constructed by mounting the silicon substrate 120 and the flexible sheet 130 on the metal plate 100. Therefore, no complicated method for construction is needed, the semiconductor laser device of the embodiment can realize the semiconductor laser device that can easily be constructed.

Also, according to the semiconductor laser device in the embodiment, the flexible sheet 130 is applied as a wiring substrate with fine pitches. Therefore, the width of the wiring pitches of the inner part can decrease to about one fifth although there is a restriction on the width of a conventional lead, which makes it possible to realize a semiconductor laser device that can have more pins accompanied by the improvement in its functionality and realize its miniaturization concurrently.

In other words, using the semiconductor laser device as the optical pick-up apparatus of the optical disc drive can realize a slim, multifunctional optical disc drive.

Also, according to the semiconductor laser device of the embodiment, the silicon substrate 120 is mounted on the metal plate 100. Therefore, as the part below the light receiving and emitting unit that is the source of heat generation is made of metal, the semiconductor laser device of the embodiment can realize a semiconductor laser device that can easily dissipate heat.

In other words, using the semiconductor laser device as the optical pick-up apparatus of the optical disc drive can realize the optical disc drive that can be used in the environmental temperature higher than the conventional one.

Note that, in the semiconductor laser device in the embodiment, a glass substrate is used for a cover that covers the silicon substrate 120 and the wire 140, but a cover is not limited to the glass substrate, any cover may be used as long as its material allows light of the semiconductor laser element 110 to pass through, for example, a plastic cover made of polyolefin and the like may be used.

### Second Embodiment

FIG. 5A is a top view of the semiconductor laser device of the second embodiment, and FIG. 5B is a section view (cut on the X-X′ line in FIG. 5A) of the semiconductor laser device in FIG. 5B. Note that the same reference numbers are assigned to the same units as the ones in FIGS. 4A and 4B, and detailed explanations on them will be omitted here.

The semiconductor laser device of the embodiment differs from the semiconductor laser device in the above-mentioned first embodiment in that its supplementary components at which optical element is set are formed on the flexible sheet, and it composes a metal plate 100, a semiconductor laser element 110, a silicon substrate 120, a flexible sheet 130, a wire 140, an optical element 200 such as a glass substrate and the like that passes through the outgoing light from the semiconductor laser element 110 and the incoming light into the light receiving elements and a supplementary component 210.

The optical element 200 is board-shaped as shown in FIG. 5B, is mounted on the supplementary component 210 and covers the silicon substrate 120 and the wire 140.

The supplementary component 210 is made of plastic, and is attached to the mounting position of the optical element 200 of the flexible sheet 130. Note that it is possible to make the supplementary component 210 become a part of the flexible sheet 130 and the supplementary component 210 may be formed altogether at the time of making the flexible sheet 130.

As explained up to this point, according to the semiconductor laser device of the embodiment, inserting the supplementary components 210 between the optical element 200 and the flexible sheet 130 prevents the optical element 200 from touching the wire 140. Therefore, processing such as making the optical element convex-shaped in order to prevent the optical element from touching the wires can be eliminated and the cost for materials of the optical element can be reduced, and the semiconductor laser device of the embodiment can realize a low-cost semiconductor laser device.

Also, according to the semiconductor laser device of the embodiment, the supplementary component 210 is attached to the mounting position of the optical element 200 of the flexible sheet 130. Therefore, the semiconductor laser device can be constructed by simply placing an optical element on the supplementary components, and the semiconductor laser device of the embodiment can realize the semiconductor laser device that can easily be constructed and whose properties are stable.

### Third Embodiment

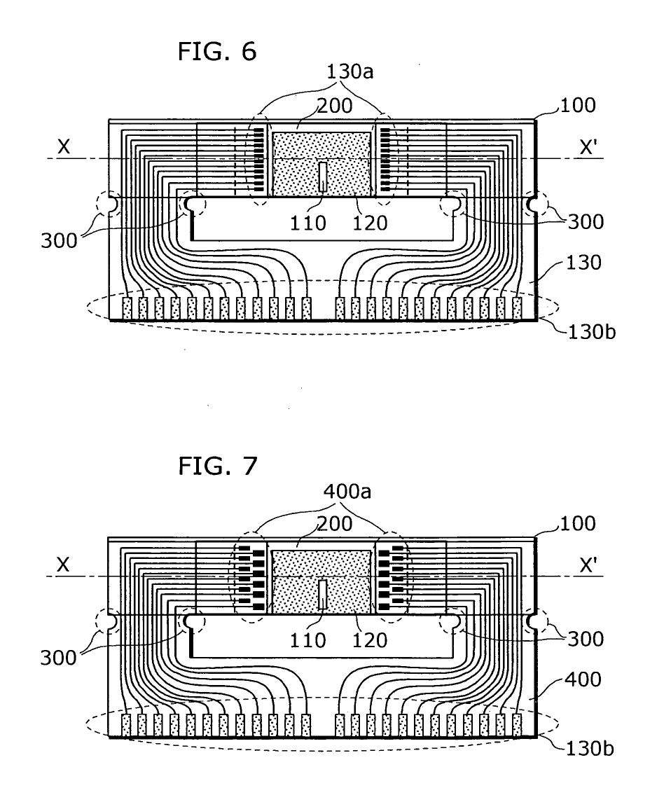

FIG. 6 is a top view of the semiconductor laser device of the third embodiment. Note that the same reference numbers are assigned to the same units in FIGS. 5A and 5B, and detailed explanations on them will be omitted here.

The semiconductor laser device of the embodiment differs from the semiconductor laser device of the above-mentioned second embodiment in that processing for making the flexible sheet easily bendable is performed, and composes a metal plate 100, a semiconductor laser element 110, a silicon substrate 120, a flexible sheet 130, an optical element 200, guide notches 300 for bending like a semi-circle that becomes a starting point of the bending and is formed as the bending part of the flexible sheet 130 outside the metal plate 100.

As explained up to this point, according to the semiconductor laser device of the embodiment, guide notches 300 that become starting points of bending are formed on the flexible sheet 130. Therefore, it is possible to prevent the occurrence of a separation at the interface between the wiring substrate and the optical element that are glued and fixed on the wiring substrate and a separation at the interface between the metal plate and the wiring substrate at the time of bending the wiring substrate, which produces an effect of realizing a semiconductor laser device that avoids such separation caused by bending of the flexible sheet.

In other words, a flexible sheet that is soft and easily bendable is used for the semiconductor laser device, and processing of making the flexible sheet bendable is performed, and thus it is possible to realize a semiconductor laser device that does not take any stress at the time of mounting the semiconductor laser device on the optical pick-up apparatus.

Note that, in the semiconductor laser device of the embodiment, guide notches 300 are formed as starting points of bending, but the starting points of bending are not limited to the guide notches 300 as long as the flexible sheet is made to be easily bendable, a guide on the back surface or a wedge-shaped guide may be formed as a starting point of bending.

### Fourth Embodiment

FIG. 7 is a top view of the semiconductor laser device in the fourth embodiment. Note that the same reference numbers are assigned to the same units and detailed explanations on them will be omitted here.

The semiconductor laser device in the embodiment differs from the semiconductor laser device in the above-mentioned third embodiment in that the areas of some pads in the inner part of the flexible sheet are big. Generally, in the wire bonding process, pads are bonded after a specific pattern in the object is recognized. Therefore, in the case where there is a gap in the positions of actual pads for wire bonding between the positions in a recognition pattern in each device, wire bonding is performed incorrectly. Specific explanation will be made below.

The semiconductor laser device of the embodiment composes a metal plate 100, a semiconductor laser element 110, a silicon substrate 120, an optical element 200 and a flexible sheet 400 having guide notches 300.

The flexible sheet 400 is divided into two on the metal plate 100, and the two divided flexible sheet 400 are placed face to face in a way that they sandwich the silicon substrate 120. Here, the space between terminals varies from an inner part 400a on the metal plate 100 to an outer part 130b outside the metal plate 100. Also, the flexible sheet 400 has plural pad-style terminal groups, and the pad-style terminals in each of the groups are placed in each of plural rows in the width direction in the inner part 400a. These terminal groups of the plural rows are placed like a so-called hounds tooth pattern, in the case of two rows for example, bigger pads are placed in the row closer to the silicon substrate 120 and smaller pads are placed in the row further to the silicon substrate 120. For example, the pads placed in the inner row (the row closer to the silicon substrate 120) are 0.23 mm×0.3 mm, and the pads placed in the outer row (the row further to the silicon substrate 120) are 0.15 mm×0.3 mm. With the above-mentioned structure, the width of the pads of terminal groups of the flexible sheet 400 is made about 80 μm that is wider than the width of the part that are touched by the wires, in other words, it is possible to make the sizes of the pads big enough to bond wires even in the case where there are some positional gaps, and thus the semiconductor laser device of the embodiment can realize a semiconductor laser device that reduces troubles in its construction.

Also, according to the semiconductor laser device of the embodiment, the pads of a terminal group in the row closer to the silicon substrate 120 are bigger than the pads of a terminal group in the row further to the silicon substrate 120 in the inner part 400a of the flexible sheet 400. Therefore, the flexibility in wire bonding (such as routing wires) can be increased and the interference between wires can be avoided, and the semiconductor laser device of the embodiment can realize a semiconductor laser device that further reduces troubles in its construction.

### Fifth Embodiment

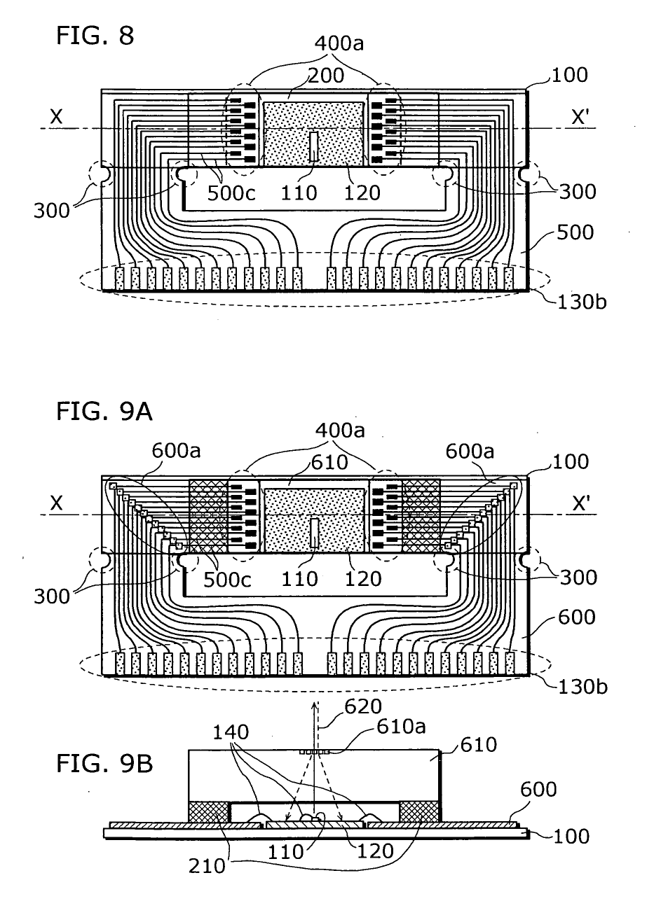

FIG. 8 is a top view of the semiconductor laser device of the fifth embodiment. Note that the same reference numbers are assigned to the same units in FIG. 7 and detailed explanations on them will be omitted here.

The semiconductor laser device of the embodiment differs from the semiconductor laser device in the above-mentioned fourth embodiment in that especially the cross sections of the wires through which high electric current flows are bigger than the cross-sections of the other wires in the flexible sheet, and composes a metal plate 100, a semiconductor laser element 110, a silicon substrate 120, an optical element 200 and a flexible sheet 500 having guide notches 300.

The flexible sheet 500 is divided into two on the metal plate 100, and the two divided flexible sheet 500 are placed face to face sandwiching the silicon substrate 120. Here, the flexible sheet 500 has an inner part 400a and an outer part 130b as a wiring terminal part, and has a wire 500c whose cross section is bigger than the other wire, for example, as a wire for electric current supply for the semiconductor laser element or a signal processing circuit. For example, in the case where the width of the other wire is 80 μm, the width of the wire 500c is made to be 150 μm. Note that, the cross section of the wire is determined based on the width or thickness of the wire.

For example, in the case where the driving current of the semiconductor laser element is used for recording, the pulse current may reach 500 mA, and the electric current of 250 mA flows on average on condition that the duty cycle is 50%, also, the thickness of the cupper foil that is the wire of the flexible sheet is generally 35 μm, in the case where the electric current of 250 mA is applied to the wire whose width is 80 μm, the temperature may reach 50° C. or more, but using the wire 500c whose width is 150 μm makes it possible to reduce the increase in temperature by half.

As mentioned up to this point, according to the semiconductor laser device in the embodiment, the flexible sheet 500 has a wire 500c whose cross section is big as a wire through which high electric current flows. Therefore, it is possible to restrain heat generation in the wire accompanied by the electric current application and reduce the thermal load on the laser as a device, it is possible to realize a semiconductor laser device that secures the reliability of the laser. Further, it is possible to realize a semiconductor laser device that reduces the load on the flexible sheet and the circuit of the silicon substrate because of the heat generation in the wired part.

In other words, it is possible to restrain the heat generation at the place other than the light receiving and emitting unit that is the source of heat generation, it is possible to realize a semiconductor laser device that can stably operate even for recording that requires realization of the operation for high-power output operation of the laser.

### Sixth Embodiment

FIG. 9A is a top view of the semiconductor laser device of the sixth embodiment, FIG. 9B is a section view (cut on the X-X′ line in FIG. 9A) of the semiconductor laser device in FIG. 9B.

Note that the same reference numbers are assigned to the same units in FIG. 8, and detailed explanations on them will be omitted here.

The semiconductor laser device of the embodiment differs from the semiconductor laser device of the above-mentioned fifth embodiment in that an optical element makes the incoming and outgoing light pass through and an optical element that diffracts incoming light from outside is mounted, and electric pads for evaluation so as to adjust and fix the optical element is formed on the flexible sheet of the metal plate. The semiconductor laser device composes a metal plate 100, a semiconductor laser element 110, a silicon substrate 120, a wire 140, a flexible sheet 600 having guide notches 300, an optical element 610 that allows incoming and outgoing light to pass through or diffract and a supplementary component 210.

The flexible sheet 600 is divided into two parts on the metal plate 100, and the two divided flexible sheet 600 is placed face to face sandwiching the silicon substrate 120. Here, the flexible sheet 600 has an inner part 400a and an outer part 130b as a wiring terminal part, and has a wire 500c, as a wire through which high electric current flows, whose cross section is bigger than the other wire. Also, the flexible sheet 600 has an electrode pad for evaluation 600a that is used for applying electric current to the semiconductor laser element 110 detecting a signal from the light receiving part by making a probe touch the electrode pad on the metal plate 100.

The optical element 610 is board-shaped as shown in FIG. 9B, and has a hologram pattern 610a that diffracts the reflection light 620 from the optical disc and launches the reflection light into the light receiving part, and the optical element is mounted on the supplementary component 210 and covers the silicon substrate 120 and the wire 140.

The supplementary component 210 is made of plastic, and attached to the mounting position of the optical element 610 of the flexible sheet 600. Note that it is possible to form the supplementary component 210 as a part of the flexible sheet 600 at the time of making the flexible sheet 600 altogether.

As explained up to this point, according to the semiconductor laser device of the embodiment, the semiconductor laser device composes an optical element 610 that diffracts the reflection light 620 from the optical disc. Therefore, the optical element mounted outside the semiconductor laser device conventionally can be integrated, and the semiconductor laser device of the embodiment can realize a semiconductor laser device that reduces the number of components in the optical disc drive.

Also, according to the semiconductor laser device of the embodiment, the flexible sheet 600 has an electrode pad for evaluation 600a on the metal plate 100. Therefore, at the time of mounting an optical element, the position is adjusted turning on the semiconductor laser element so as to confirm the signal obtained from the light detection part of the silicon substrate, therefore, making the probe electrically touch the electrode pad for evaluation on the metal plate is surer than making the probe electrically touch the outer part of the flexible sheet, the semiconductor laser device of the embodiment can realize the semiconductor laser device that can easily be adjusted optically even in the case of having more pins.

### Seventh Embodiment

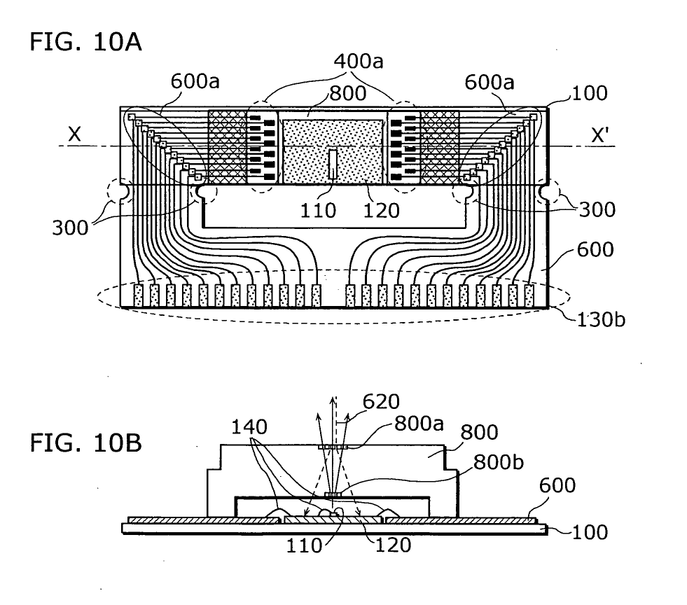

FIG. 10A is a top view of the semiconductor laser device of the seventh embodiment, and FIG. 10B is a section view (cut on the X-X′ line in FIG. 10A) of the semiconductor laser device. Note that the same reference numbers are assigned to the same units in FIGS. 9A and 9B, and detailed explanations on them will be omitted here.

The semiconductor laser device of the embodiment composes a metal plate 100, a semiconductor laser element 110, a silicon substrate 120, a wire 140, a flexible sheet 600 having guide notches 300, and an optical element 800 that allows the incoming and outgoing light pass through and diffract.

The optical element 800 has a hologram pattern 800a that diffracts the reflection light 620 from the optical disc 750 on a surface further from the semiconductor laser element 110 and allows the reflection light 620 to reach the light receiving part, and a grating pattern 800b that diffracts laser beam and forms three beams on a surface closer to the semiconductor laser element 110, and it is mounted on the flexible sheet 600 in a way that it covers the silicon substrate 120 and the wire 140 after adjusting the optical axis to light emitting points. Here, the optical element 800 is a convex and its peripheral part is an arc whose center is the center point of the optical element 800.

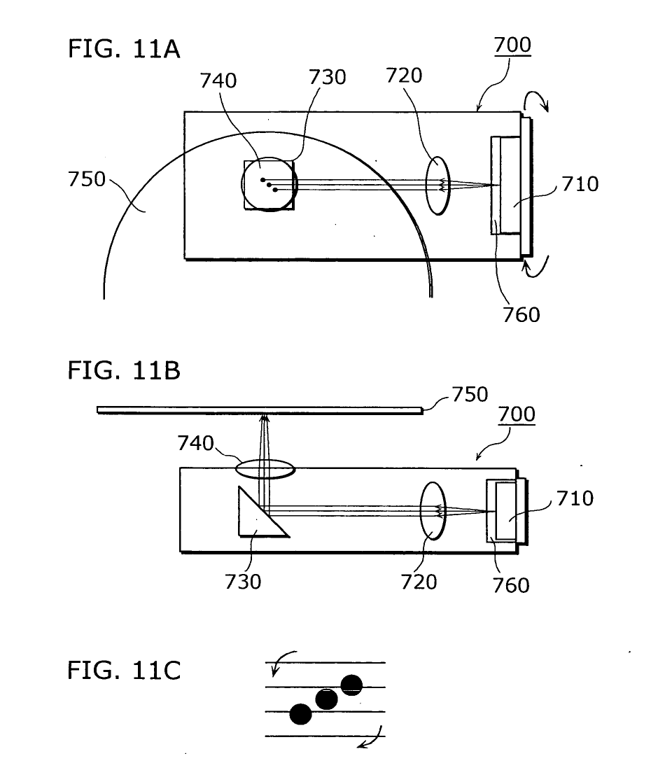

FIG. 11A is a top view of the optical pick-up apparatus 700 on which the above-mentioned semiconductor laser device is mounted, and FIG. 11B is a section view of the optical pick-up apparatus 700.

The optical pick-up apparatus 700 is an optical pick-up apparatus of three beam optical system, and comprises a semiconductor laser device 710, a collimate lens 720, a mirror 730, an object lens 740 and a convex-shaped insertion part 760 with an arc into which the semiconductor laser device 710 is inserted in a way that it is rotatable.

In the optical pick-up apparatus 700 having the above-mentioned structure, the laser beam divided into three by the optical element in the semiconductor laser device 710 passes through the collimate lens 720, the mirror 730 and the object lens 740 and is irradiated on the optical disc 750.

Here, three beams are irradiated on positions shown in, for example, FIG. 11C on the optical disc 750, rotating the semiconductor laser device 710 adjusts the positions on the optical disc 750 on which the three beams are irradiated to predetermined positions. This adjustment eliminates the possibility of a problem that it becomes impossible to record accurately because of displacements of the axis caused by the shifting of the object lens in the light pick-up apparatus of a recording system, and thus secure track detection can be performed.

The semiconductor laser device 710 is attached to the light pick-up apparatus 700 in a way that the arc of the optical element 800 of the semiconductor laser device 710 matches the arc of the insertion part 760, and the adjustment of positions on which three beams are irradiated in the optical disc 750 is performed by rotating the semiconductor laser device 710 according to the arc of the insertion part 760.

As explained up to this point, according to the semiconductor laser device of the embodiment, the peripheral part of the optical element 800 is an arc, and the arc matches the arc of the insertion part 760. Also, the optical element 800 is mounted on the flexible sheet 600 after adjusting the optical axis based on the light emitting points. Therefore, only the rotation and adjustment must be done at the time of mounting the semiconductor laser device of the optical pick-up apparatus, the semiconductor laser device of the embodiment can realize a semiconductor laser device that can easily be constructed on the light pick-up apparatus.

In other words, the convex-shaped outer arc of a package that is the rotation and adjustment part at the time of mounting an optical element on the optical pick-up apparatus does not match the optical axes of light emitting points in the case of the semiconductor laser device described in U.S. Pat. No. 3,412,609 publication, not only the rotation and adjustment but also the adjustment in the surface that is vertical to the ongoing direction of the laser beam are needed, but the semiconductor laser device of the embodiment requires only the rotation and adjustment because the optical axes of the optical element has already been adjusted at the time of mounting an optical element on the optical pick-up apparatus.

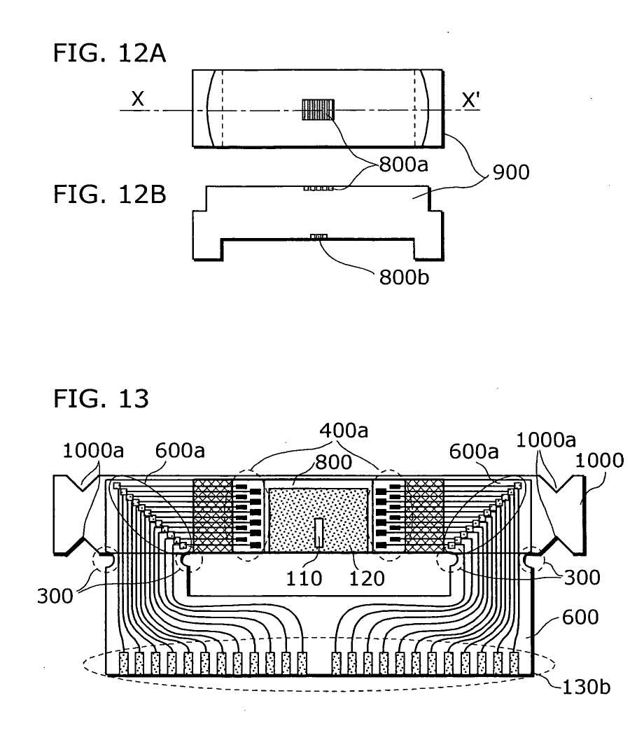

Note that, in the semiconductor laser device in the embodiment, the peripheral part of the optical element 800 is an arc, and the arc is used for the rotation and adjustment. However, as shown in the top view and the cross-section view of the optical element 900 in FIGS. 12A and 12B, the optical element 900 has a gap in the end part, an arc in the upper peripheral part of the gap, and it may use them for the rotation and adjustment.

Also, the optical element 800 is a convex and is mounted on the flexible sheet 600. However, it is possible that the semiconductor laser device composes plastic supplementary components which are attached to the mounting positions of the optical element of the flexible sheet, and the optical element is board-shaped and mounted on the supplementary components.

### Eight Embodiment

The semiconductor laser device in this embodiment of the present invention will be explained with reference to figures below.

FIG. 13 is a top view of the semiconductor laser device of the eighth embodiment. Note that the same reference numbers are assigned to the same units as FIGS. 10A and 10B, and detailed explanations on them will be omitted here.

The semiconductor laser device of the embodiment differs from the semiconductor laser device in the above-mentioned seventh embodiment in that its outer metal plate extends off, and also, notches for fixation are formed on the metal plate, and composes a semiconductor laser element 110, a silicon substrate 120, a flexible sheet 600 having guide notches 300, an optical element 800 that allows the incoming and outgoing light to pass through and diffract, and the metal plate 1000 made of cupper on which nickel and gold are plated.

The metal plate 1000 has a width such as 3 mm that is substantially the same as the bigger one of the width of the silicon substrate 120 and the width of the flexible sheet 600. Here, the metal plate 1000 has exposed parts at the both ends that are not covered by the flexible sheet 600, and has notches for fixation 1000a that are placed face to face sandwiching the exposed parts in the width direction at the long sides.

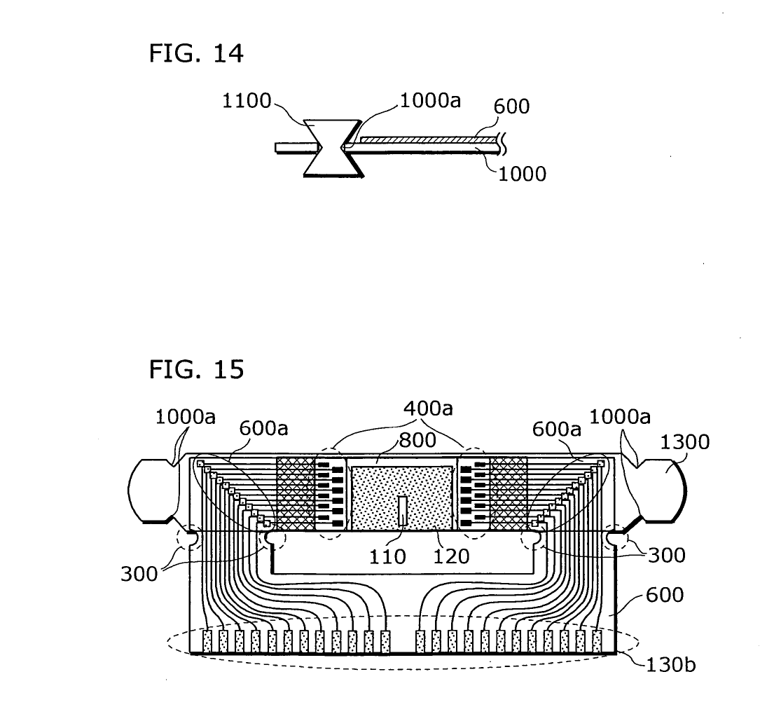

As shown in the cross-section view of the semiconductor laser device of FIG. 14, the light axes of the optical element 800 is adjusted in the semiconductor laser device having the above-mentioned structure in a way that the metal plate 1000 is surely fixed without displacement on the X-Y surface and in the direction of Z axis by making the clump jig 1100 sandwich the notches for fixation 1000a and the optical element 800 is made to touch the flexible sheet 600. At this time, the notches for fixation 1000a are formed at long sides of the metal plate 1000. As a reason, in the case where notches for fixation are formed at short sides of the metal plate 1000, there emerges a problem that the silicon substrate 120 comes off from the metal plate 1000 because deformation of the area in which the center part, that is, the light receiving and emitting unit is mounted is generated when the metal plate 1000 are sandwiched and fixed by the notches for fixation.

As explained up to this point, according to the semiconductor laser device of the embodiment, the metal plate 1000 has notches for fixation 1000a at the long sides. Therefore, it is possible to surely fix the metal plate on which a semiconductor laser element and a silicon substrate are mounted at the time of placing and adjusting the optical element in a way that the metal plate is not displaced on the X-Y surface and in the direction of the axis of Z, and thus it is possible to realize a semiconductor laser device that makes it easier to adjust the optical axes of the optical element.

Also, according to the semiconductor laser device of the embodiment, the metal plate 1000 has exposed parts that are not covered by the flexible sheet 600 at both ends. Therefore, making the exposed parts of the front surface of this metal plate touch the casing of the optical pick-up apparatus via silicon grease and the like makes it possible to dissipate heat widely not only from the back surface but also front surface, and thus the semiconductor laser device of the embodiment can realize a semiconductor laser device that can dissipate heat efficiently.

In other words, using this semiconductor laser device as the optical pick-up apparatus of the optical disc drive makes it possible to realize the disc drive of recording system whose output speed is high and that can be used at an environmental temperature higher than a conventional one.

### Ninth Embodiment

FIG. 15 is a top view of the semiconductor laser device 1210 of the ninth embodiment. Note that the same reference numbers are assigned to the same units as the ones in FIG. 13, and detailed explanations on them will be omitted here.

The semiconductor laser devices 1210 of the embodiment composes a semiconductor laser element 110, a silicon substrate 120, a flexible sheet 600 having guide notches 300, an optical element 800, and a metal plate 1300 made of cupper on which nickel and gold are plated.

The metal plate 1300 has a width such as 3 mm that is substantially the same as the bigger one of the width of the silicon substrate 120 and the width of the flexible sheet 600. Here, the metal plate 1300 has exposed parts at the both ends that are not covered by the flexible sheet 600, and has notches for fixation 1000a at the long sides (the horizontal sides in the figure), and lengths of the short sides (the vertical sides in the figure) of the metal plate 1300 are shorter in outside the notches for fixation 1000a than in insides the notches for fixation 1000a. Also, the metal plate 1300 has arcs whose centers are the center points of the optical element 800 in both ends.

The semiconductor laser device 1210 is mounted at the optical pick-up apparatus making the arc of the metal plate 1300 of the semiconductor laser device 1210 touch the arc in the insertion part of the optical pick-up apparatus in a way that they touch each other, and the irradiation positions of three beams in the optical disc 750 are adjusted by rotating the semiconductor laser device 1210 along with the arcs.

As explained up to this point, according to the semiconductor laser device, the metal plate 1300 has arcs whose centers are the center parts of the optical element 800 at both ends, and the metal plate 1300 is rotated and adjusted at the time of mounting the semiconductor laser device 1210 on the optical pick-up apparatus. Therefore, the rotation and adjustment is performed without putting load on the optical element, the connection part and the like, and the semiconductor laser device of the embodiment can realize a semiconductor laser device that prevents a breakdown that disabling obtaining desired properties from occurring because of the load in placing and adjusting the optical pick-up apparatus.

Also, according to the semiconductor laser device of the embodiment, the widths of both ends of the metal plate 1300 are narrower than the widths of the parts on which the flexible sheet 600 of the metal plate 1300 are mounted. Therefore, both the ends of the metal plate are not extended off the optical disc drive that is required to be slimmed down to 3 mm even in the case where the semiconductor laser device is rotated and adjusted in mounting the semiconductor laser device on the optical pick-up apparatus, and the semiconductor laser device of the embodiment can realize the semiconductor laser device that can be stored within the desired size after the optical disc is mounted.

Also, according to the semiconductor laser device of the embodiment, notches for fixation 1000a are formed at the long sides of the metal plate 1300. Therefore, fixing the metal plate by sandwiching the notches for fixation using a clump jig makes it possible to hold the semiconductor laser device at the time of the rotation and adjustment in mounting the device on the optical pick-up apparatus, the semiconductor laser device of the embodiment can realize the semiconductor laser device that can be easily constructed.

Here, in the semiconductor laser device of the above-mentioned first to ninth embodiments, the flexible sheet divided into two on the metal plate, the divided two flexible sheets sandwich the silicon board and are pulled down to outside the metal plate altogether. However, the flexible sheet may not be pulled out to outside the metal plate, and further, it may not divided into two on the metal plate. At this time, as a wiring substrate on the metal plate, a print substrate may be used instead of a flexible sheet.

### Tenth Embodiment

The optical pick-up apparatus in this embodiment of the present invention will be explained with reference to figures.

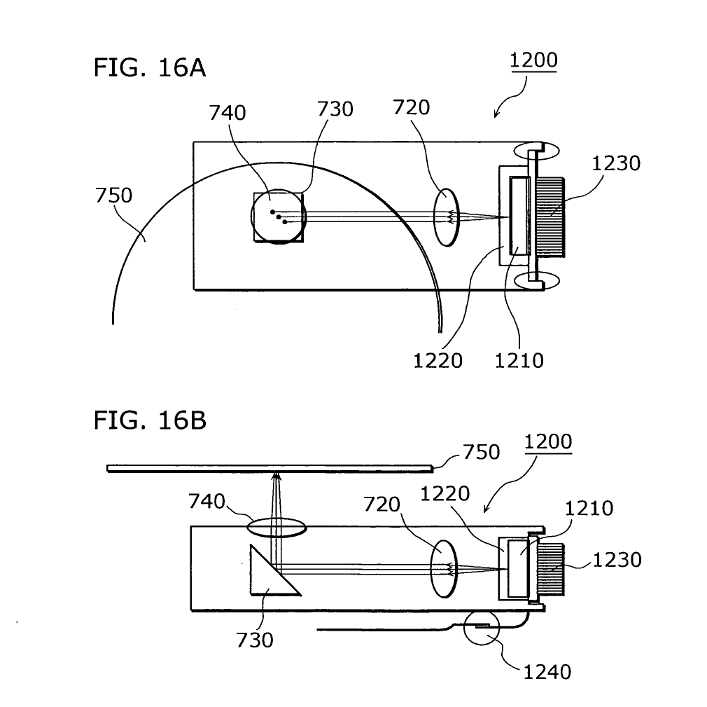

FIG. 16A is a top view of the optical pick-up apparatus 1200 of the tenth embodiment, and FIG. 16B is a section view of the optical pick-up apparatus 1200. Note that the same reference numbers are assigned to the same units in FIGS. 11A, 11B and 11C, and detailed explanations on them will be omitted here.

The optical pick-up apparatus 1200 of the embodiment is the optical pick-up apparatus of three beam optical system, and comprises a collimate lens 720, a mirror 730, an object lens 740, a semiconductor laser device 1210 in the ninth embodiment, an insertion part 1220 into which a semiconductor laser device 1210 is inserted in a rotatable state and a heat dissipation block 1230 that is glued and fixed on the back of the metal plate of the semiconductor laser device 1210 using glue such as silicon thermal conductive glue.

Here, as shown in FIG. 16B, a flexible sheet with wires in the semiconductor laser device 1210 is connected to another flexible sheet in the outer part.

As explained up to this point, according to the optical pick-up apparatus of the embodiment, the optical pick-up apparatus comprises a heat dissipation block 1230 on the back of the metal plate 1300 of the semiconductor laser device 1210, and the metal plate 1300 touches the optical pick-up apparatus 1200. Therefore, the heat dissipation area is widely enlarged and its heat dissipation effect is improved, which makes it possible to dissipate heat generated by the semiconductor laser element to outside efficiently, and thus the optical pick-up apparatus of the embodiment can realize the optical pick-up apparatus that can stably operate thanks to its high heat dissipation property.

Also, according to the optical pick-up apparatus of the embodiment, the semiconductor laser device 1210 applies a flexible sheet 600 as a wiring substrate, and the flexible sheet of the semiconductor laser device 1210 are connected to another flexible sheet in the solder-connected part 1240 outside the optical pick-up apparatus 1200. Therefore, the distance between the optical element and the outer part to be a solder-connected part of the flexible sheet can be twice the distance of the conventional structure, and thus the optical pick-up apparatus of the embodiment can realize the optical pick-up apparatus that widely reduces the thermal load on the semiconductor laser device itself at the time of mounting the semiconductor laser device on the optical pick-up apparatus.

In other words, widening the distance between the solder mounting part and the above-mentioned components eliminates the possibility that optical element and the glue that fixes the optical element is heated over the heat resistant temperatures by the thermal conductivity at the time of wire connecting by the solder, nonreflective prevention film that is formed on the grating pattern or the hologram pattern of the optical element is peeled off and positions of the optical element becomes misaligned because of softening of the glue, and its properties and reliance deteriorates.

Note that, in the optical pick-up apparatus of the embodiment, the metal plate 1300 of the semiconductor laser device 1210 and the heat dissipation block 1230 are glued and fixed by silicon glue, but glue is not limited to this as long as it is glue with a high thermal conductivity, for example, it may be a graphite sheet with a high thermal conductivity.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention can be used for a semiconductor laser device, especially for an optical pick-up and the like of an optical disc drive apparatus.

1. A semiconductor laser device comprising:
a light receiving and emitting unit having light emitting elements and light receiving elements;
a first wiring substrate; and
a metal plate on which the light receiving and emitting unit, and the first wiring substrate are mounted,
wherein the light receiving and emitting unit, and the first wiring substrate are arranged next to each other on the metal plate,
the first wiring substrate has a first terminal group composed of a plurality of first terminals connected to the light receiving and emitting unit, and
the width of the metal plate is substantially the same as a bigger one of widths of the first wiring substrate and the light receiving and emitting unit.

2. The semiconductor laser device according to claim 1, further comprising:
a second wiring substrate mounted on the metal plate facing the first wiring substrate sandwiching the light receiving and emitting part,
wherein the second wiring substrate has a second terminal group composed of a plurality of second terminals connected to the light receiving and emitting unit, and
a width of the second wiring substrate is substantially the same as the width of the first wiring substrate.

3. The semiconductor laser device according to claim 2, further compising:
an external wiring substrate that pulls out wires of the first and second wiring substrates outside the metal plate,
the external wiring substrate has a plurality of external terminals electrically connected to the terminals in the first and second terminal groups, and
space between the external terminals is wider than space between terminals in the first terminal group and space between terminals in the second terminal group.

4. The semiconductor laser device according to claim 3,
wherein the first and second wiring substrates and the external wiring substrate are a flexible sheet where metal wires are wrapped in plastic.

5. The semiconductor laser device according to claim 4,
wherein the first and second terminal groups are respectively composed of a plurality of the first and second terminals that are arranged in a width direction that is perpendicular to a longitudinal direction where the light receiving and emitting unit, and the first and second wiring substrates are arranged, and
the first and second wiring substrates have a plural rows of the first and second terminal groups.

6. The semiconductor laser device according to claim 5,
wherein a part of wires of the first and second wiring substrates and the external wiring substrate have bigger cross-sectional areas than the other wires.

7. The semiconductor laser device according to claim 6,
wherein the metal plate has exposed parts where neither the first and second wiring substrates nor the light receiving and emitting unit, is mounted at both ends of the longitudinal direction where the light receiving and emitting unit, and the first and second wiring substrates are arranged.

8. The semiconductor laser device according to claim 5,
wherein the metal plate has exposed parts where neither the first and second wiring substrates nor the light receiving and emitting unit, is mounted at both ends of the longitudinal direction where the light receiving and emitting unit, and the first and second wiring substrates are arranged.

9. The semiconductor laser device according to claim 4,
wherein a part of wires of the first and second wiring substrates and the external wiring substrate have bigger cross-sectional areas than the other wires.

10. The semiconductor laser device according to claim 4,
wherein the metal plate has exposed parts where neither the first and second wiring substrates nor the light receiving and emitting unit, is not mounted at both ends of the longitudinal direction where the light receiving and emitting unit, and the first and second wiring substrates are arranged.

11. The semiconductor laser device according to claim 3,
wherein the first and second terminal groups are respectively composed of a plurality of the first and second terminals that are arranged in a width direction that is perpendicular to a longitudinal direction where the light receiving and emitting unit, and the first and second wiring substrates are arranged, and
the first and second wiring substrates have a plural rows of the first and second terminal groups.

12. The semiconductor laser device according to claim 3,
wherein a part of the first and second wiring substrates and the external wiring substrate have bigger cross-sectional areas than the other wires.

13. The semiconductor laser device according to claim 3,
wherein the metal plate has exposed parts where neither the first and second wiring substrates nor the light receiving and emitting unit, is mounted at both ends of the longitudinal direction where the light receiving and emitting unit, and the first and second wiring substrates are arranged.

14. The semiconductor laser device according to claim 2,
wherein the first and second terminal groups are respectively composed of a plurality of the first and second terminals that are arranged in a width direction that is perpendicular to a longitudinal direction where the light receiving and emitting unit, and the first and second wiring substrates are arranged, and
the first and second wiring substrates have a plural rows of the first and second terminal groups.

15. The semiconductor laser device according to claim 2,
wherein the metal plate has exposed parts where neither the first and second wiring substrates nor the light receiving and emitting unit, is not mounted at both ends of the longitudinal direction where the light receiving and emitting unit, and the first and second wiring substrates are arranged.
